(19) United States
(12) Patent Application Publication
(10) Pub. No.: US 2006/0199035 A1
(43) Pub. Date: Sep. 7, 2006

(54) Organic electroluminescent device

(75) Inventors: Stelios A. Choulis, San Jose, CA (US); Dmytro Poplavskyy, San Jose, CA (US)

Correspondence Address: FISH & RICHARDSON P.C., PO BOX 1022, MINNEAPOLIS, MN, 55440-1022, US

(73) Assignee: Osram Opto Semiconductors GmbH & Co.

(21) Appl. No.: 11/070,047

(22) Filed: Mar. 2, 2005

(51) Int. Cl. H01L 51/54; H05B 33/12

(52) U.S. Cl. 428/690; 428/917; 428/446; 428/448; 313/504; 313/506

(57) ABSTRACT

An electroluminescent device incorporating high electron affinity additives of siloles or silacyclopentadienes, and their derivatives. The above additives can be incorporated within the emissive layer or interlayer or in both of these layers.

### BACKGROUND

A typical structure of an organic electroluminescent device consists of an anode (e.g. indium-tin-oxide (ITO)), a hole injection layer (e.g. PEDOT:PSS or polyaniline), a hole transport layer (e.g. an amine-based organic material), an electroluminescent layer, and a cathode layer (e.g. barium covered with aluminum). The function of the hole injection layer is to provide efficient hole injection into subsequent layers. In addition, hole injection layer also acts as a buffer layer to smooth the surface of the anode and to provide a better adhesion for the subsequent layer. The function of the hole transport interlayer is to transport holes, injected from the hole injection layer, to the electroluminescent layer, where recombination with electrons will occur and light will be emitted. This layer usually consists of a high hole mobility organic material, such as TPD, NPD, amine-based starburst compounds, amine-based spiro-compounds and so on. Another function of the hole transporting interlayer is to move the recombination zone away from the interface with the hole injection layer. The function of the electroluminescent layer is to transport both types of carriers and to efficiently produce light of desirable wavelength from electron-hole pair (exciton) recombination. The function of the electron injection layer is to efficiently inject electrons into the electroluminescent layer.

Conjugated polymers or small-molecules are of increasing interest as materials for electroluminescent layers of OLED devices, offering the potential for low fabrication cost, easy processing and flexibility. One of the limitations for the wide-scale commercialization of such OLED devices is that they have relatively poor lifetime and air stability properties. Many factors are responsible for limited operational lifetime of such devices, some of which, but not all, include degradation of injecting electrodes, degradation of light-emitting properties of the emitting material, deterioration of charge transporting properties of materials, that constitute a devices, and many others. Furthermore organic compounds tend to be unstable in air. Strong trapping caused by molecular oxygen impurities degrades electron transport properties, quenches emission, and thus limit the stability of the device in the presence of air.

One of the approaches to increase operational life-time of organic electroluminescent devices concentrates on the device architecture, i.e. modifying device structure to include additional functional layers, such as an electron blocking layer, hole transporting layer, an electron transporting, and so on. This approach also includes changing layers' thicknesses to optimize the lifetime. (See U.S. patent application Ser. No. 10/869,147, bearing attorney docket number 2004P04185US01, entitled “Thick Light Emitting Polymers to Enhance OLED Efficiency and Lifetime” filed on Jun. 15, 2004). Another approach is to design material(s) that will be stable under given operational conditions in a given device architecture. For example, an approach to improve lifetime of organic electroluminescent devices is proposed, whereby a small amount of carbon nanostructures is added to the electroluminescent material (see U.S. patent application Ser. No. 10/992,037, bearing attorney docket number 2004P19347US, entitled “Organic Electroluminescent Device with Prolonged Operational Lifetime” filed on Nov. 17, 2004). Air stability of the selected materials is also of crucial importance to maintain stable operation in presence of air. Even after encapsulation environmental factors like moisture and oxygen can affect device stability.

### BRIEF DESCRIPTION OF THE DRAWINGS

FIG. 1 shows a cross-sectional view of an embodiment of an EL device 405 according to at least one embodiment of the invention.

FIG. 2 shows a cross-sectional view of an embodiment of an EL device 505 according to at least a second embodiment of the invention.

FIG. 3 illustrates an exemplary additive utilized in one or more embodiments of the invention.

### DETAILED DESCRIPTION

In at least one embodiment of the invention, an OLED device is disclosed in which a high electron affinity additive, namely siloles, or silacyclopentadienes, or derivatives of either of these, is added to an electroluminescent material to form the emissive layer of the device. In at least one embodiment of the invention, high electron affinity additive can also be added to other layers of the device, even if their function does not include light emission.

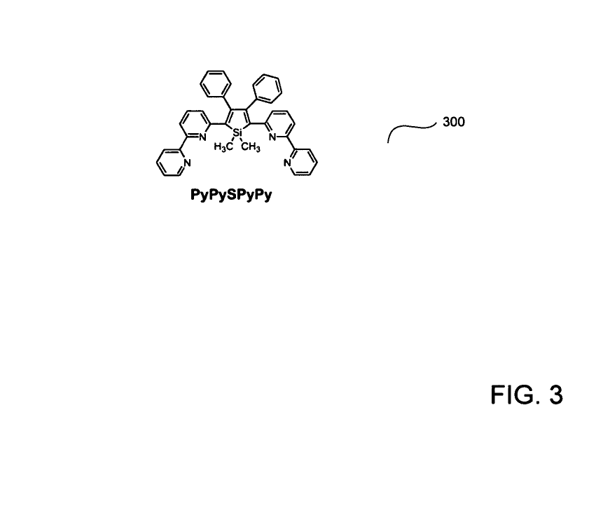

Siloles or silacyclopentadienes or their derivatives have been proposed as a new class of electron transporting material. A silole is a silicon-substituted cyclopentadiene with strong electron accepting properties. The high electron affinity (low LUMO (Lowest Unoccupied Molecular Orbital) level) of these materials is attributed to the σ*-n* conjugation between the σ* orbital of the two exocyclic Si-C σbonds and the n* orbital of the butadiene moiety on the silicon ring. A chemical structure of a representative silole derivative named PyPySPyPy is shown in FIG. 3 (H. Murata et al., Chemical Physics Letters, 339, 161, 2001).

The high electron affinity and high aromaticity of their anionic species are two unique electronic properties of the silole derivatives that lead to a trap-free electron transport in solid amorphous films. Furthermore silole derivatives are very stable in air unlike most organic semiconductors which are unable to maintain electron mobility in presence of air. A large solid state electron affinity is crucial for the formation of stable anions in an organic solid and for reduction of trapping effects caused by oxygen.

Typical concentrations of the abovementioned additive when used in fabricating the electroluminescent layer are in the range 0-10 weight percent, if the additive itself acts as a strong luminescence quencher and higher concentrations would lead to undesirable reduction in overall device electroluminescence efficiency. But the additive concentration can be increased if emissive additives such as emissive siloles, emissive silole derivatives, emissive silacyclopentadienes, or emissive silacyclopentadiene derivatives are used.

When siloles, or silacyclopentadienes, or derivatives of either of these are added into non-emitting functional layers of the devices, higher concentrations of additives can be used, in the range 0-50 wt %, as no detrimental effect on device efficiency is expected in this case. The advantages of the invention over similar approaches, e.g. when using fullerenes, are the air stability and also the possibility of using emissive additives. The difference here is that we use high electron affinity siloles, or silacyclopentadienes, or derivatives of either of these which are air stable and can act not only as a luminescence quencher but also as an emissive component itself. The siloles, or silacyclopentadienes, or derivatives of either of these can be blended directly with any electroluminescent polymer, or small molecule, either fluorescent or phosphorescent.

Incorporation of high electron affinity additives into the functional (emissive and non-emissive) layers can be done in a variety of ways that include one or more of: 1) blending additives with the functional organic material; 2) chemically attaching or cross-linking additives to the functional organic material, e.g. as a part of the chain in the copolymer structure or as a pendant group; and/or 3) co-evaporation of additives with the functional organic small molecule materials.

The use of high electron affinity additives, in accordance with the invention, is not limited to any particular type of organic materials and can be used with the fluorescent and phosphorescent conjugated polymers, or with the fluorescent and phosphorescent small molecule materials. Examples of small molecule materials include triphenyldiamine (TPD), α-napthylphenyl-biphenyl (NPB), tris(8-hydroxyquinolate)aluminum(Alq₃), tris(2-phenylpyridine)iridium(Ir(ppy)₃), and so on, examples of polymers include poly(p-phenylene vinylene) (PPV) and derivatives, polyfluorenes and their derivatives, polyfluorene homopolymer and copolymers, spiro-based polymers and so on.

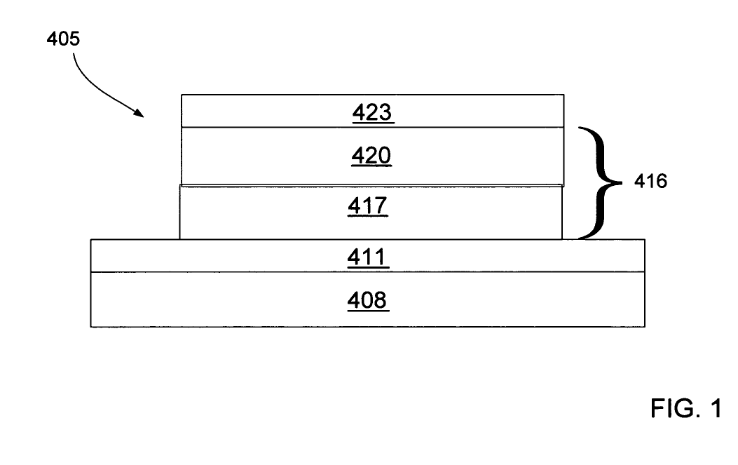

FIG. 1 shows a cross-sectional view of an embodiment of an EL (electro-luminescent) device 405 according to at least one embodiment of the invention. The EL device 405 may represent one pixel or sub-pixel of a larger display. As shown in FIG. 1, the EL device 405 includes a first electrode 411 on a substrate 408. As used within the specification and the claims, the term “on” includes when layers are in physical contact or when layers are separated by one or more intervening layers. The first electrode 411 may be patterned for pixilated applications or remain un-patterned for backlight applications.

One or more organic materials are deposited to form one or more organic layers of an organic stack 416. The organic stack 416 is on the first electrode 411. The organic stack 416 includes a hole injection/anode buffer layer (“HIL/ABL”) 417 and emissive layer (EML) 420. If the first electrode 411 is an anode, then the HIL/ABL 417 is on the first electrode 411. Alternatively, if the first electrode 411 is a cathode, then the active electronic layer 420 is on the first electrode 411, and the HIL/ABL 417 is on the EML 420. The OLED device 405 also includes a second electrode 423 on the organic stack 416. In accordance with at least one embodiment of the invention, high electron affinity additives can be used in one or more layers of the organic stack, particularly in the EML 420. Examples of these additives include siloles, or silacyclopentadienes, or derivatives of either of these and the like. Other layers than that shown in FIG. 1 may also be added including barrier, charge transport/injection, and interface layers between or among any of the existing layers as desired. Some of these layers, in accordance with the invention, are described in greater detail below.

Substrate 408:

The substrate 408 can be any material that can support the organic and metallic layers on it. The substrate 408 can be transparent or opaque (e.g., the opaque substrate is used in top-emitting devices). By modifying or filtering the wavelength of light which can pass through the substrate 408, the color of light emitted by the device can be changed. The substrate 408 can be comprised of glass, quartz, silicon, plastic, or stainless steel; preferably, the substrate 408 is comprised of thin, flexible glass. The preferred thickness of the substrate 408 depends on the material used and on the application of the device. The substrate 408 can be in the form of a sheet or continuous film. The continuous film can be used, for example, for roll-to-roll manufacturing processes which are particularly suited for plastic, metal, and metallized plastic foils. The substrate can also have transistors or other switching elements built in to control the operation of an active-matrix OLED device. A single substrate 408 is typically used to construct a larger display containing many pixels (EL devices) such as EL device 405 repetitively fabricated and arranged in some specific pattern.

First Electrode 411:

In one configuration, the first electrode 411 functions as an anode (the anode is a conductive layer which serves as a hole-injecting layer and which comprises a material with work function typically greater than about 4.5 eV). Typical anode materials include metals (such as platinum, gold, palladium, and the like); metal oxides (such as lead oxide, tin oxide, ITO (Indium Tin Oxide), and the like); graphite; doped inorganic semiconductors (such as silicon, germanium, gallium arsenide, and the like); and doped conducting polymers (such as polyaniline, polypyrrole, polythiophene, and the like).

The first electrode 411 can be transparent, semi-transparent, or opaque to the wavelength of light generated within the device. The thickness of the first electrode 411 can be from about 10 nm to about 1000 nm, preferably, from about 50 nm to about 200 nm, and more preferably, is about 100 nm. The first electrode layer 411 can typically be fabricated using any of the techniques known in the art for deposition of thin films, including, for example, vacuum evaporation, sputtering, electron beam deposition, or chemical vapor deposition.

In an alternative configuration, the first electrode layer 411 functions as a cathode (the cathode is a conductive layer which serves as an electron-injecting layer and which comprises a material with a low work function). The cathode, rather than the anode, is deposited on the substrate 408 in the case of, for example, a top-emitting OLED. Typical cathode materials are listed below in the section for the “second electrode 423”.

HIL/ABL 417:

The HIL/ABL 417 has good hole conducting properties and is used to effectively inject holes from the first electrode 411 to the EML 420 (via the HT interlayer 418, see below). The HIL/ABL 417 is made of polymers or small molecule materials. For example, the HIL/ABL 417 can be made of tertiary amine or carbazole derivatives both in their small molecule or their polymer form, conducting polyaniline (“PANI”), or PEDOT:PSS (a solution of poly(3,4-ethylenedioxythiophene) (“PEDOT”) and polystyrenesulfonic acid (“PSS”) available as Baytron P from HC Starck). The HIL/ABL 417 can have a thickness from about 5 nm to about 1000 nm, and is conventionally used from about 50 to about 250 nm.

Other examples of the HIL/ABL 417 include any small molecule materials and the like such as plasma polymerized fluorocarbon films (CFx) with preferred thicknesses between 0.3 and 3 nm, copper phthalocyanine (CuPc) films with preferred thicknesses between 10 and 50 nm.

The HIL/ABL 417 can be formed using selective deposition techniques or nonselective deposition techniques. Examples of selective deposition techniques include, for example, ink jet printing, flex printing, and screen printing. Examples of nonselective deposition techniques include, for example, spin coating, dip coating, web coating, and spray coating. A hole transporting and/or buffer material is deposited on the first electrode 411 and then allowed to dry into a film. The dried film represents the HIL/ABL 417. Other deposition methods for the HIL/ABL 417 include plasma polymerization (for CFx layers), vacuum deposition, or vapour phase deposition (e.g. for films of CuPc).

EML 420:

For organic LEDs (OLEDs) as the EL device 405, the EML 420 contains at least one organic material that emits light. These organic light emitting materials generally fall into two categories. The first category of OLEDs, referred to as polymeric light emitting diodes, or PLEDs, utilize polymers as part of EML 420. The polymers may be organic or organo-metallic in nature. As used herein, the term organic also includes organo-metallic materials. Light-emission in these materials may be generated as a result of fluorescence or phosphorescence.

Preferably, these polymers are solvated in an organic solvent, such as toluene or xylene, and spun (spin-coated) onto the device, although other deposition methods are possible too. Devices utilizing polymeric active electronic materials in EML 420 are especially preferred.

The light emitting organic polymers in the EML 420 can be, for example, EL polymers having a conjugated repeating unit, in particular EL polymers in which neighboring repeating units are bonded in a conjugated manner, such as polythiophenes, polyphenylenes, polythiophenevinylenes, or poly-p-phenylenevinylenes or their families, copolymers, derivatives, or mixtures thereof. More specifically, organic polymers can be, for example: polyfluorenes; poly-p-phenylenevinylenes that emit white, red, blue, yellow, or green light and are 2-, or 2, 5—substituted poly-p-pheneylenevinylenes; polyspiro polymers.

In addition to polymers, smaller organic molecules that emit by fluorescence or by phosphorescence can serve as a light emitting material residing in EML 420. Unlike polymeric materials that are applied as solutions or suspensions, small-molecule light emitting materials are preferably deposited through evaporative, sublimation, or organic vapor phase deposition methods. There are also small molecule materials that can be applied by solution methods too. Combinations of PLED materials and smaller organic molecules can also serve as active electronic layer. For example, a PLED may be chemically derivatized with a small organic molecule or simply mixed with a small organic molecule to form EML 420. Examples of electroluminescent small molecule materials include tris(8-hydroxyquinolate) aluminum (Alq₃), anthracene, rubrene, tris(2-phenylpyridine)iridium(Ir(ppy)3), triazine, any metal-chelate compounds and derivatives of any of these materials.

In addition to active electronic materials that emit light, EML 420 can include a material capable of charge transport. Charge transport materials include polymers or small molecules that can transport charge carriers. For example, organic materials such as polythiophene, derivatized polythiophene, oligomeric polythiophene, derivatized oligomeric polythiophene, pentacene, triphenylamine, and triphenyldiamine. EML 420 may also include semiconductors, such as silicon, gallium arsenide, cadmium selenide, or cadmium sulfide.

In accordance with at least one embodiment of the invention, high electron affinity additives are used in addition to the typical electroluminescent materials described above in fabricating the EML 420. Examples of such additives include siloles, silacyclopentadienes, silole derivatives, or silacyclopentadiene derivatives. A silole is a silicon-substituted cyclopentadiene with strong electron accepting properties. The high electron affinity (low LUMO (Lowest Unoccupied Molecular Orbital) level) is attributed to the σ*-n* conjugation between the σ* orbital of the two exocyclic Si-C σ bonds and the n* orbital of the butadience moiety on the silicon ring. The chemical structure of a representative silole derivative named PyPySPyPy is shown in FIG. 3. The electron affinity of the additives should be preferably higher than the electron affinity of the electroluminescent materials used in EML 420.

Typical concentrations of the abovementioned additive when used in fabricating the electroluminescent layer are in the range 0 to 10 weight percent, if the additive itself acts as a strong luminescence quencher and higher concentrations would lead to undesirable reduction in overall device electroluminescent efficiency. But the additive concentration can be increased if emissive additives such as emissive siloles, emissive silacyclopentadiene, or emissive derivatives of either are used. In such case, the concentration of high electron affinity additives in the EML can be 0 to up to 50 weight percent.

All of the organic layers such as HIL/ABL 417 and EML 420 can be ink-jet printed by depositing an organic solution or by spin-coating, or other deposition techniques. This organic solution may be any “fluid” or deformable mass capable of flowing under pressure and may include solutions, inks, pastes, emulsions, dispersions and so on. The liquid may also contain or be supplemented by further substances which affect the viscosity, contact angle, thickening, affinity, drying, dilution and so on of the deposited drops.

Further, any or all of the layers 417, 418 and 420 may be cross-linked or otherwise physically or chemically hardened as desired for stability and maintenance of certain surface properties desirable for deposition of subsequent layers.

Alternatively, if small molecule materials are used instead of polymers, the HIL/ABL 417, the HT interlayer 418, the EML 420 can be deposited through evaporation, sublimation, organic vapor phase deposition, or in combination with other deposition techniques.

Second Electrode (423)

In one embodiment, second electrode 423 functions as a cathode when an electric potential is applied across the first electrode 411 and the second electrode 423. In this embodiment, when an electric potential is applied across the first electrode 411, which serves as the anode, and second electrode 423, which serves as the cathode, photons are released from active electronic layer 420 and pass through first electrode 411 and substrate 408.

While many materials, which can function as a cathode, are known to those of skill in the art, most preferably a composition that includes aluminum, indium, silver, gold, magnesium, calcium, lithium fluoride, cesium fluoride, sodium fluoride, and barium, or combinations thereof, or alloys thereof, is utilized. Aluminum, aluminum alloys, and combinations of magnesium and silver or their alloys can also be utilized. In some embodiments of the invention, a second electrode 423 is fabricated by thermally evaporating in a three layer or combined fashion lithium fluoride, calcium and aluminum in various amounts.

Preferably, the total thickness of second electrode 423 is from about 10 to about 1000 nanometers (nm), more preferably from about 50 to about 500 nm, and most preferably from about 100 to about 300 nm. While many methods are known to those of ordinary skill in the art by which the first electrode material may be deposited, vacuum deposition methods, such as physical vapor deposition (PVD) are preferred.

Often other processes such as washing and neutralization of films, addition of masks and photo-resists may precede cathode deposition. However, these are not specifically enumerated as they do not relate specifically to the novel aspects of the invention. Other fabrication processes like adding metal lines to connect the anode lines to power sources may also be desirable. Other layers (not shown) such as a barrier layer and/or getter layer and/or other encapsulation scheme may also be used to protect the electronic device. Such other processing steps and layers are well-known in the art and are not specifically discussed herein.

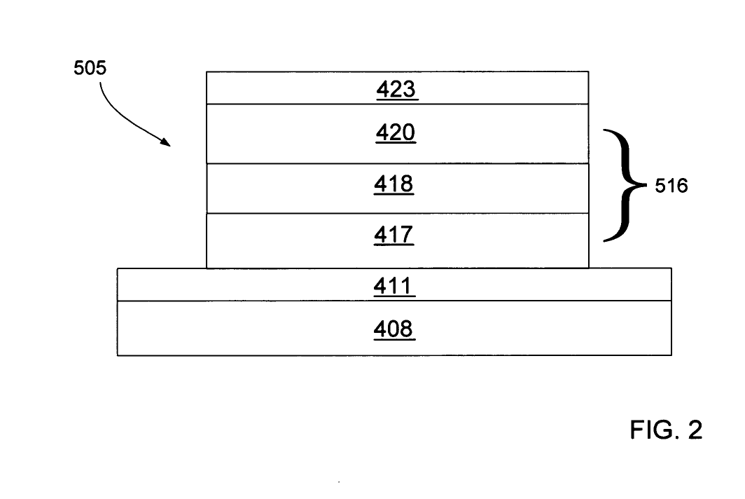

FIG. 2 shows a cross-sectional view of an embodiment of an EL device 505 according to at least a second embodiment of the invention. Like numbered elements in devices 405 and 505 have a similar description with, as given above, and will not be repeated. The device 505 is identical in most aspects to device 405 of FIG. 1 except for the following. Device 505 has an organic stack 516 which includes an additional HT interlayer 418.

HT Interlayer 418:

The functions of the HT interlayer 418 are among the following: to assist injection of holes into the EML 420, reduce exciton quenching at the anode, provide better hole transport than electron transport, and block electrons from getting into the HIL/ABL 417 and degrading it. Some materials may have one or two of the desired properties listed, but the effectiveness of the material as an interlayer is believed to improve with the number of these properties exhibited. Through careful selection of the hole transporting material, an efficient interlayer material can be found. Examples of criteria that can be used are as follows: a criterion that can be used to find materials that can help injection of holes into the EML 420 is that the HOMO (Highest Occupied Molecular Orbital) levels of the material bridge the energy barrier between the anode and the EML 420, that is the HOMO level of the HT interlayer 418 should be in between the HOMO levels of the anode and the EML 420. Charge carrier mobilities of the materials can be used as a criterion to distinguish materials that will have better hole transport than electron transport. Also, materials that have higher LUMO (Lowest Unoccupied Molecular Orbital) levels than the LUMO of the EML 420 will present a barrier to electron injection from the EML 420 into the HT interlayer 418, and thus act as an electron blocker. The HT interlayer 418 is fabricated from a hole transporting material that may consist at least partially of or may derive from one or more following compounds, their derivatives, moieties, etc: polyfluorene derivatives, poly(2,7-(9,9-di-n-octylfluorene)-(1,4-phenylene-((4-secbutylphenyl)imino)-1,4-phenylene) and derivatives which include cross-linkable forms, non-emitting forms of poly(p-phenylenevinylene), triarylamine type material (e.g. triphenyldiamine (TPD), α-napthylphenyl-biphenyl (NPB)), thiopene, oxetane-functionalized polymers and small molecules etc. In some embodiments of the invention, the HT interlayer 418 is fabricated using a cross-linkable hole transporting polymer.

In accordance with at least one embodiment of the invention, high electron affinity additives can also be incorporated into HT (hole transporting) interlayer 418. Examples of such additives include siloles, silacyclopentadiene, or derivatives of either of these. The electron affinity of the additives should be preferably higher than the electron affinity of the electroluminescent materials used in EML 420. These additives are discussed in greater detail above.

The HT interlayer 418 can be ink-jet printed by depositing an organic solution, by spin-coating, by vacuum deposition, by vapor phase deposition, or other deposition techniques whether selective or non-selective. Further, if required, the HT interlayer 418 may be cross-linked or otherwise physically or chemically hardened as desired for stability and maintenance of certain surface properties desirable for deposition of subsequent layers.

In alternate other embodiments of the invention, not specifically depicted, the HT interlayer 418 can be the only layer in the organic stack that has high electron affinity additives such as siloles, silacyclopentadienes, and derivatives of either of these, added thereto. In such embodiments, the emissive layer would comprise at least an electroluminescent material, but not any high electron affinity additives.

FIG. 3 illustrates an exemplary high electron affinity additive utilized in one or more embodiments of the invention. Additive 300 can be incorporated by blending, chemical bonding, and cross-linking with the functional material (such as the hole transporting polymer or emissive polymer) and/or evaporation with the functional material. Additive 300 is a silole derivative given the nomenclature PyPySPyPy with a chemical composition 2,5-bis(6′-(2′,2″-bipyridyl))-1,1-dimethyl-3,4-diphenyl silole.

As any person of ordinary skill in the art of electronic device fabrication will recognize from the description, figures, and examples that modifications and changes can be made to the embodiments of the invention without departing from the scope of the invention defined by the following claims.

1. An electroluminescent device having a plurality of stacked layers, comprising:
an anode layer;
a hole injection/anode buffer layer disposed over said anode layer;
an emissive layer, said emissive layer capable of emitting light, said emissive layer fabricated from an electroluminescent material and high electron affinity additives, said additives including at least one of siloles, silacyclopentadiene, silole derivatives, or silacyclopentadiene derivatives; and
a cathode layer disposed above said emissive layer.

2. The device according to claim 1 further comprising:
a hole transporting interlayer disposed between said hole injection/anode buffer layer and said emissive layer.

3. The device according to claim 1 wherein at least one of said hole injection/anode buffer layer and said emissive layer are formed at least in part using at least one polymer organic material.

4. The device according to claim 1 wherein at least one of said hole injection/anode buffer layer and said emissive layer are formed at least in part using at least one small molecule material.

5. The device according to claim 1 wherein said additives are also air stable.

6. The device according to claim 2 wherein said hole transporting interlayer are formed at least in part using at least one polymer organic material.

7. The device according to claim 1 wherein the concentration of said additives is between 0 and 10 weight percent.

8. The device according to claim 1 wherein if said additives are emissive, the concentration of said additives is between 0 and 50 percent by weight.

9. The device according to claim 1 wherein said electroluminescent material is a polymer.

10. The device according to claim 9 wherein said conjugated polymer includes a conjugated poly-p-phenylenevinylene polymer.

11. The device according to claim 9 wherein said conjugated polymer includes a conjugated polyspiro polymer.

12. The device according to claim 9 wherein said conjugated polymer includes a conjugated fluorene polymer.

13. The device according to claim 1 wherein said electroluminescent materials and said additives are blended.

14. The device according to claim 1 wherein said electroluminescent materials and said additives form a co-polymer.

15. The device according to claim 9 wherein said electroluminescent materials and said additives are cross-linked.

16. The device according to claim 2 wherein said hole transporting interlayer incorporates high electron affinity additives therein, said additives including at least one of siloles, silacyclopentadiene, silole derivatives, or silacyclopentadiene derivatives.

17. The device according to claim 16 wherein said additives are also air stable

18. The device according to claim 1 wherein said hole transporting interlayer incorporates high electron affinity additives therein, said additives including at least one of siloles, silacyclopentadiene, silole derivatives, or silacyclopentadiene derivatives.

19. The device according to claim 18 wherein said additives are also air stable

20. The device according to claim 1 wherein said emissive layer includes materials having at least one of: a polymer, conjugated polymer, a co-polymer, a monomer, a cross-linkable polymer, a polymer blend and a polymer matrix.

21. An electroluminescent device having a plurality of stacked layers, comprising:
an anode layer;
a hole injection/anode buffer layer disposed over said anode layer;
an emissive layer, said emissive layer capable of emitting light, said emissive layer fabricated from an electroluminescent material;
a hole transporting interlayer disposed between said hole injection/anode buffer layer and said emissive layer, said hole transporting interlayer incorporates high electron affinity additives therein, said additives including at least one of siloles, silacyclopentadiene, silole derivatives, or silacyclopentadiene derivatives; and a cathode layer disposed above said emissive layer.

22. The device according to claim 21 wherein said additives are also air stable.
